(19) United States
(12) Patent Application Publication
(10) Pub. No.: US 2026/0302909 A1
(43) Pub. Date: Oct. 1, 2026

(54) AN ELECTROHYDRODYNAMIC PUMP FOR PUMPING A DIELECTRIC FLUID

(71) Applicant: APR TECHNOLOGIES AB, Enköping (SE)

(72) Inventors: Robert THORSLUND, Sigtuna (SE); Are BJÖRNEKLETT, Västerås (SE); Peter NILSSON, Sundbyberg (SE); Patrik LUNDIN, Solna (SE); Mikael ANTELIUS, Täby (SE); Henrik LÖFGREN, Uppsala (SE)

(21) Appl. No.: 19/478,097

(22) PCT Filed: Mar. 12, 2024
(86) PCT No.: PCT/SE2024/050224

§ 371 Date: Oct. 23, 2025

(30) Foreign Application Priority Data
Apr. 27, 2023 (SE) 2350505-0

(51) Int. Cl. H02K 44/06

(52) U.S. Cl. CPC H02K 44/06

(57) ABSTRACT

Described is, among other things, an EHD pump comprising at least a first electrode (200) and at least a second electrode (210). The first electrode comprises a first grid (202) and the second electrode comprises a second grid (212), each of the first and second grids have grid openings formed by bridges (204, 214), wherein the second grid is asymmetric and having a different size with respect to the first grid.

### TECHNICAL FIELD

The present disclosure relates to a pump for pumping a dielectric fluid.

### BACKGROUND

Fluids can be pumped using different technologies, usually some type of pump. One pump technology used for pumping fluids is known as electrohydrodynamic (EHD) pumps. An EHD pump uses electric fields to move a dielectric fluid. The moved fluid can typically be used as coolant in a thermal loop to dissipate heat generated by heat generating components such as electrical components. The EHD pump has few components and no moving parts. These features make the EHD pump attractive in applications where simplicity and robustness of the system are a priority.

For example, WO 2017/127017 describes a circulating system using an EHD pump in a closed circulating system.

Technologies that can benefit from systems based on circulating a fluid using an EHD pump include satellites, such as telecommunication satellites, which are approaching the technology limits of existing on-board thermal management systems. The power dissipation needs of these satellites increases to meet the growing requirements for broadcasting, broadband multimedia and mobile communications services. Micro, nano, or ‘cube’ satellites, which require low-mass heat removal from electronic components (satellite on-chip), typically need more compact thermal management systems for maintaining a high performance.

Technologies that can benefit from systems based on circulating a fluid using an EHD pump also include other heat generating electronic devices such as battery modules for cars, heavy equipment, peak shaving, energy storage. It can also be used in applications such as electronic devices attached to heat sinks, finned heatsinks with forced or natural air convection cooling. Also, it can be used in telecommunication equipment.

The active cooling systems using forced flows of fluids can be used to improve the cooling efficiency. Electrohydrodynamic (EHD) pumps where ionized particles or molecules interact with an electric field and power a flow of a dielectric fluid can then be used.

Even though EHD pumps are known, there is still a need for an improved EHD pump.

### SUMMARY

It is an object of the present invention to provide an improved EHD pump.

This object and/or others are, at least partly, obtained by the EHD pump as set out in the appended claims.

As has been realized by the inventor, by providing an EHD pump having the collector and the emitter formed as grids and by making the grids asymmetric, an improved capacity of the EHD pump can be obtained.

In accordance with the invention, an EHD pump is provided. The EHD pump comprises at least a first electrode and at least a second electrode. The first electrode comprises a first grid and the second electrode comprises a second grid. Each of the first and second grids have grid openings formed by bridges, such that each of the first and second grids has at least one grid opening delimited by bridges on all sides of the grid opening, wherein the second grid is asymmetric with respect to the first grid in that the second grid has a different size of the grid openings with respect to the size of the grid openings of the first grid. Hereby an EHD pump with grid shaped collector and emitter and having an improved performance can be provided. The EHD pump will at the same time be formed in a rigid and robust manner in that wires forming grids for both the emitter and collector are provided. In accordance with one embodiment, the second grid has a different numbers of grid openings with respect to the number of grid openings of the first grid. Hereby an easy to implement asymmetric grid configuration can be obtained. In particular the second grid can have fewer grid openings than the first grid. For example, the second grid can be given only one single grid opening.

In accordance with one embodiment, at least one of the electrodes, such as the emitter electrode, can be provided with a grid that are elongated (thicker) in the flow direction, such that a height (depth) of the bridges as seen in the flow direction is greater than a width as seen in a direction orthogonal to the flow direction.

In accordance with one embodiment, at least one of the first grid and the second grid has at least one rectangular shaped grid opening. In particular all grid openings can be rectangular shaped grid openings. Hereby an easy to manufacture yet robust EHD pump can be obtained.

In accordance with one embodiment, at least one bridge has a protrusion on the side facing a grid opening. Hereby additional asymmetry that can promote the flow capacity of the EHD pump is obtained. Also, a plurality of protrusions can be provided. For example, the at least one bridge has a plurality of protrusions on the side facing the grid opening.

In accordance with one embodiment, the surface of at least one the grid is provided with a thin film coating and/or a surface modification. Hereby the flow capacity of the EHD pump can be further improved.

### BRIEF DESCRIPTION OF THE DRAWINGS

The present invention will now be described in more detail by way of non-limiting examples and with reference to the accompanying drawings, in which:

FIG. 1 is a view illustrating a pumping mechanism in an EHD pump,

FIG. 2 is a view of an asymmetric configuration of the pumping mechanism in an EHD pump in accordance with a first embodiment,

FIG. 3 is a view of an asymmetric configuration of the pumping mechanism in an EHD pump in accordance with a second embodiment,

FIG. 4 is a view of an asymmetric configuration of the pumping mechanism in an EHD pump in accordance with a third embodiment, and

FIG. 5 is a view of an asymmetric configuration of the pumping mechanism in an EHD pump in accordance with a fourth embodiment.

### DETAILED DESCRIPTION

The invention will now be described more fully hereinafter with reference to the accompanying drawings, in which certain embodiments of the invention are shown. The invention may, however, be embodied in many different forms and should not be construed as limited to the embodiments set forth herein; rather, these embodiments are provided by way of example so that this disclosure will be thorough and complete, and will fully convey the scope of the invention to those skilled in the art. For example, like or similar components of different embodiments can be exchanged between different embodiments. Some components can be omitted from different embodiments. Like numbers refer to like elements throughout the description. Also, some well-known components can be omitted in the description so as to not obscure the disclosure. For example, many conventional components that are normally used in an EHD pump are not described. Such components can typically comprise but are not limited to:
A distancing member separating the emitter and collector to keep the emitter and collector separated at a determined distance. The distancing member can be of some non-conducting material such as an isolator formed by a ceramic or plastics material.
A housing. The housing can enclose the EHD pump body and can be made a plastics material or a metal material.
a fixing structure holding the pumping parts in place.
a set of electrical connections for connecting the EHD pump to a drive circuit that is used to operate the EHD pump.

Other parts can also be present all depending on the type of implementation.

It is to be understood that the features from different embodiments can be combined and that no feature of an embodiment is essential unless explicitly so expressed. Hence, the person skilled in the art can select which features and dimensions that are deemed to be advantageous for a particular implementation.

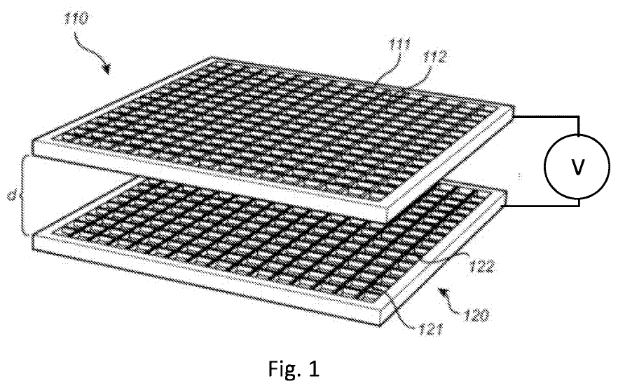

In FIG. 1, an EHD pump 100 as described in WO 2017/127017 is shown. The EHD pump 100 comprises a first electrode, or emitter 110, comprising bridges 111 and joints 112 forming a grid that allows a fluid to flow through the emitter 110. The grid can be formed by wires joined together such that grid openings are formed having wires on all sides of the grid opening. The emitter 110 may have a lateral extension in a plane perpendicular to the intended flow direction. In FIG. 1, a second electrode, or collector 120, comprises bridges 121 and joints 122 that are arranged in a similar grid the one described with reference to the emitter 110. Consequently, the collector 120 may have a lateral extension in a plane perpendicular to the direction of the flow such that both the emitter 110 and the collector 120 are parallel to each other at a distance d. Thus, there can be a first electrode; and a second electrode offset from the first electrode in a downstream direction of a flow of the circulating fluid, the first electrode and the second electrode can be connectable to a voltage source V.

Thus, the EHD pump structure of FIG. 1 comprises two grids spaced apart. The term ‘grid’ can here typically refer to any structure comprising bridges that are joined to each other, such as to, e.g., a grating, net, or honeycomb structure, etc. The bridges and the joints define open areas of the grid which admit a fluid flow through the open areas that can also be termed grid openings. A grid will therefore have at least one grid opening delimited by bridges on all sides of the grid opening. The bridges can typically be formed by wires and the grid can then be termed a wire grid. The EHD pump can promote a flow of a dielectric fluid in a defined direction of flow.

The terms ‘direction of flow’ or ‘flow direction’ typically refers to the main direction of the resulting net flow of fluid passing through the EHD pump during operation thereof. These terms may also be referred to as ‘intended direction of flow’.

Examples of fluids, i.e., liquids and gases, that can be pumped by example embodiments include e.g., dielectrics such as acetone, alcohols, helium, nitrogen, esters and fluorocarbon-based fluids such as e.g., Fluorinert™ Novec™, or Opteon™.

The two grids of the EHD pump form a first electrode and a second electrode, respectively. The first electrode may also be referred to an “emitter” or “emitter electrode”, and the second electrode may be referred to as “collector” or “collector electrode”.

The first and/or second electrodes can comprise a material that has a relatively good ability of emitting electrons and is chemically stable, or inert, in relation to the pumped fluid. Further, the material may have a relatively high temperature resistance. Examples of such materials include, e.g., Pt, Ni, Ru, Rh, Pd, W, stainless steel and any combination or alloy thereof.

The first electrode can comprise bridges and joints forming the grid structure.

Further, at least a portion of at least one of the bridges may have a maximum height in a direction parallel to the direction of the flow and a maximum gauge in a direction orthogonal to the direction of the flow, where the maximum height may be larger than the maximum gauge.

By forming a grid of bridges that have a relatively large height in relation to their gauge, the grid may be relatively rigid in terms of its ability to carry loads in the height direction of the bridges, or the direction of the flow. Thereby, a relatively rigid electrode is provided, which is less prone to bend or deform, especially in the direction of the flow, and hence the risk for, e.g., short-circuiting of the device may be reduced. Further, the relatively rigid and stable grid may still have a relatively large open area which may provide a relatively low flow resistance being met by the fluid passing through the grid. Further, the relatively high and narrow bridges may reduce the amount of material required for forming a relatively stable and rigid grid, which may reduce both weight and cost of the device. By using a relatively rigid grid, the need for additional support structures may be reduced and a relatively well defined and constant spacing between the first and second electrodes may be achieved. The spacing may, e.g., be within the range of 10-4000 μm, and more preferably in the range of 500-2000 μm.

With their relatively large height, the bridges also provide a relatively large contact surface between the grid structure and the passing fluid, which may facilitate any interactions between the electrode and the fluid, such as, e.g., diffusion of material and/or injection of ions or electrons.

The distance, d, or spacing, between the first and the second electrode may be varied so as to control the strength of the electric field being induced between the electrodes.

While the EHD pump of FIG. 1 can meet many needs, there is always a desire to improve the performance of an EHD pump. As has been discovered, by providing both the first and second electrodes as grids where the grids of the first and second electrodes are asymmetrical with respect to each other, an improved flow can be provided in the EHD pump.

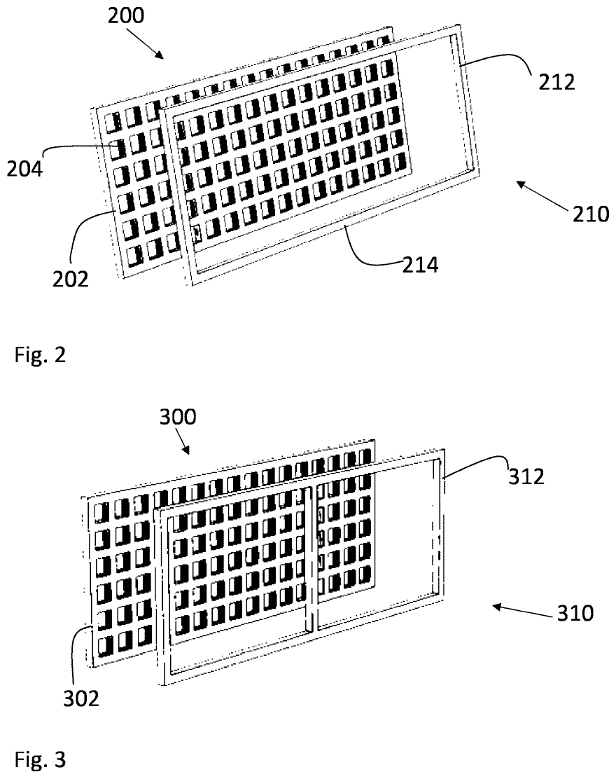

In FIG. 2 such an asymmetric configuration of the first and second electrode are shown in a first exemplary embodiment. In the embodiment of FIG. 2, a first electrode 200 acting as an emitter is provided. Further a second electrode 210 acting as a collector is provided. The first electrode 200 comprises a first grid 202 and the second electrode 210 also comprises a grid, a second grid 212. Thus, both the first electrode 200 and the second electrode 210 comprises grids 202, 212, but the grid 202 of the first electrode 200 has a different configuration than the grid 212 of the second electrode.

In the exemplary embodiment of FIG. 2, the first grid 202 has a plurality of grid openings delimited by bridges 204 in the same manner as described above in conjunction with FIG. 1. The second grid 212 only has one, single, grid opening delimited by such bridges 214. By configuring the grids 202, 212 to be asymmetric, for example by having different numbers of grid openings, different types of grids such as different sizes and or shapes of the grid openings or different sizes of the grids themselves, an improved flow in the pumping mechanism of an EHD pump can be achieved. In the exemplary embodiment of FIG. 2, the grid openings are rectangular. However, one or both of the grids can have other shapes such as hexagonal depending on the implementation.

In accordance with one embodiment, at least one of the electrodes, such as the emitter electrode, can be provided with a grid that is elongated (thicker) in the flow direction, such that a height (depth) of the bridges as seen in the flow direction is greater than a width as seen in a directions orthogonal to the flow direction. This configuration can improve the electric field properties with respect to the corona discharge, which is an underlying mechanism accelerating the fluid between the electrodes. In such an embodiment, the bridges will have different dimensions in the different grids 202 and 212. In other words, height and or width of the bridges can be different between the electrode grids 202, 212. In such a configuration having different dimensions of the bridges in the respective grids 202 and 212, the number of openings and/or the shape of the openings can also be different for the respective grids 202 and 212.

This improvement can stem from the resulting asymmetry in the formed electrical double layers in the surrounding fluid as a build-up of oppositely charged particles on the grid surfaces is prevented. The asymmetry will also alter the electric field in the fluid, which can act to improve the pump performance. The asymmetry can also make the EHD pump more tolerant to particles and bubbles present in the fluid since typically larger openings can be formed whilst still maintaining the performance.

In FIG. 3 another asymmetric configuration of the first and second electrode are shown in a second exemplary embodiment. In the embodiment of FIG. 3, a first electrode 300 acting as an emitter is provided. Further a second electrode 310 acting as a collector is provided. The first electrode 300 comprises a first grid 302 and the second electrode 310 also comprises a grid, a second grid 312. In the exemplary embodiment of FIG. 3, the first grid 302 has a plurality of grid openings delimited by bridges as described above in conjunction with FIG. 1. The second grid 312 has fewer, here only two, grid openings delimited by such bridges.

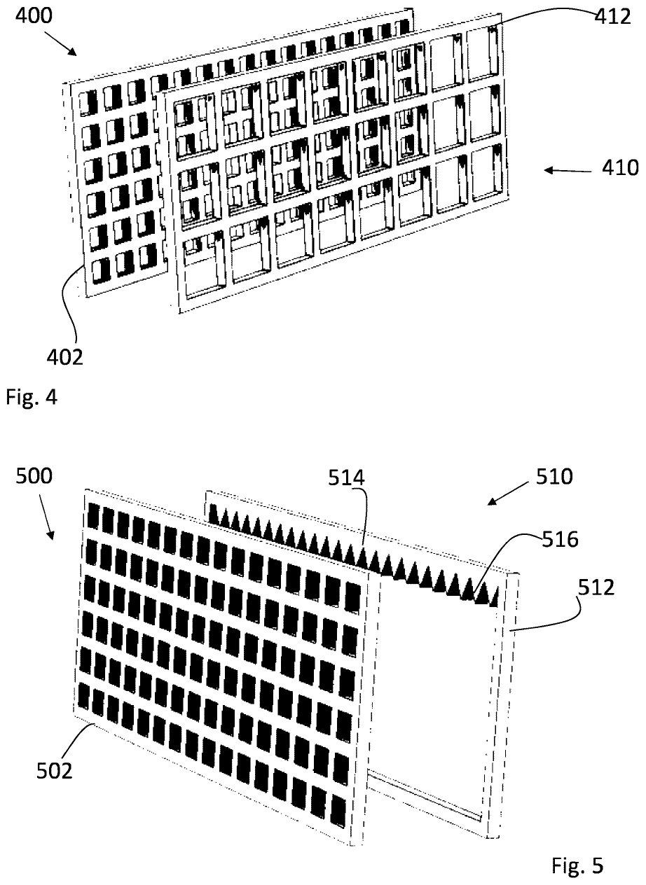

In FIG. 4 yet another asymmetric configuration of the first and second electrode are shown in a third exemplary embodiment. In the embodiment of FIG. 4, a first electrode 400 acting as an emitter is provided. Further a second electrode 410 acting as a collector is provided. The first electrode 400 comprises a first grid 402 and the second electrode 410 also comprises a grid, a second grid 412. In the exemplary embodiment of FIG. 4, the first grid 402 has a plurality of grid openings, typically at least 10 or more such at at least 20. delimited by bridges as described above in conjunction with FIG. 1. The second grid 412 also has a plurality of grid openings, but fewer grid openings than the first grid, delimited by such bridges.

In FIG. 5 another asymmetric configuration of the first and second electrode are shown in a fourth exemplary embodiment. In the embodiment of FIG. 5, a first electrode 500 acting as a collector is provided. Further a second electrode 510 acting as an emitter is provided. The first electrode 500 comprises a first grid 502 and the second electrode 510 also comprises a grid, a second grid 512. In the exemplary embodiment of FIG. 5, the first grid 502 has a plurality of grid openings delimited by bridges as described above in conjunction with FIG. 1 and FIG. 2. The second grid 512 (the emitter in this configuration) in this example having only a single grid opening as in FIG. 2, and also has, at least one, and preferably a plurality of protrusions 516 formed on at least one bridge 514. The protrusions 516 acts to promote the flow in the pumping mechanism of an EHD pump as the electrical field strength is higher locally at the narrow tips of the protrusions. The protrusions can have the shape of a tip that can be triangular in shape. The tip can point away from the bridge 514 such that the tip faces away from the bridge and points towards into the grid opening. In accordance with some embodiments a plurality of protrusions 516 are formed on at least one bridge 514. The plurality of protrusions 516 can in accordance with one embodiment be formed by forming the bridges with a serrated side facing a grid opening. The emitter tip protrusions pointing into the collector grid opening.

The surface of the asymmetric emitter and collector grids as described herein can be coated. It can be advantageous to surface coat the emitter and/or collector grid. To alter the performance and durability, the surface can be coated or the surface structure can be made to have a particular structure. For example, the surface can be coated with: Platinum, Rhenium, Ruthenium, Lead, Tungsten (Wolfram), or alloys and combinations of the materials. In another embodiment or as a supplement, the surface structure can be given a particular structure. For example, the surface structure can be provided with microstructures (micro needles, micro pyramids, other structures) created by for example by electroplating, sandblasting, acid, heat-treatment, roll-impinging, additive manufacturing, or laser ablating, stamping. The surface microstructures and/or coating can further enhance the performance of the pump by creating a surface that is more prone to emitting or absorbing electrons. The coating or altered surface could also be advantageous in terms of lifetime enhancement.

A plurality of EHD pumps as described herein can also be series connected to increase to flow even more. The EHD pumps can then be spaced apart with a distance at least the distance between the grids of one single pump. Typically, a spacing of 3-5 times the distance of the grid of a single pump can then be used to distance two EHD pumps provided in series.

Using the EHD pump with grid structure for both the emitter and the collector and having asymmetric configuration of the two grids can provide an improved flow capacity while maintaining the advantages afforded by a grid shaped emitter and collector in the EHID pump. For example, a higher/thicker collector electrode is beneficial for capturing and neutralizing more of the charged particles in the fluid as it passes by. This is because its contact area with the fluid is large. This can allow for a higher pump pressure-rise at higher flow-rate, because if the liquid is not sufficiently neutralized at each collector, then charges will drift from one electrode-pair to the next and provide a backwards-pumping effect before the next emitter, where the electric field is locally reversed. The emitter cannot usually derive a benefit from height/thickness in any similar way, and so the emitter is better kept short/thin relative to the collector.

Further, by having asymmetry in the sense of an emitter grid decorated with sharp tips or edges, and a collector with only a flat or blunt surface, is advantageous due to the enhanced uni-directionality of the EHD-pumping effect.

Also, by allowing for asymmetry of the grids, as such, can allow for larger openings for bubbles and particles etc. to pass more easily. The asymmetry of the grids can further make larger grid-openings much easier to construct, when taking into account both mechanical stability and E-field shape.

1. An EHD pump comprising at least a first electrode and at least a second electrode, the first electrode comprising a first grid and the second electrode comprising a second grid, each of the first and second grids having grid openings formed by bridges and such that each of the first and second grids has at least one grid opening delimited by bridges on all sides of the grid opening, wherein the second grid is asymmetric with respect to the first grid in that the second grid has a different size of the grid openings with respect to the size of the grid openings of the first grid.

2. The EHD pump according to claim 1, wherein the second grid has a different shape of the grid openings with respect to the grid openings of the first grid

3. The EHD pump according to claim 1, wherein the second grid has a different numbers of grid openings with respect to the number of grid openings of the first grid.

4. The EHD pump according to claim 3, wherein the second grid has fewer grid openings than the first grid.

5. The EHD pump according to claim 4, wherein one of the first grid and the second grid has only one single grid opening.

6. The EHD pump according to claim 1, wherein at least one of the first grid and the second grid has at least one rectangular shaped grid opening.

7. The EHD pump according to claim 1, wherein at least one bridge has a protrusion on the side facing a grid opening.

8. The EHD pump according to claim 7, wherein the at least one bridge has a plurality of protrusions on the side facing the grid opening.

9. The EHD pump according claim 1, wherein at least one of the grids is elongated in the flow direction, such that a height as seen in the flow direction is greater than a width as seen in a direction orthogonal to the flow direction.

10. The EHD pump according to claim 1, wherein the surface of at least one the grids is provided with a thin film coating and/or a surface modification.
